(19) United States
(12) Patent Application Publication
(10) Pub. No.: US 2024/0241452 A1
(43) Pub. Date: Jul. 18, 2024

(54) METROLOGY APPARATUS AND LITHOGRAPHIC APPARATUS

(71) Applicant: ASML Netherlands B.V., Veldhoven (NL)

(72) Inventors: Arjan Johannes Anton Beukman, Son en Breugel (NL); Duygu Akbulut, Eindhoven (NL)

(21) Appl. No.: 18/558,910

(22) PCT Filed: Apr. 5, 2022
(86) PCT No.: PCT/EP22/59003

§ 371 Date: Nov. 3, 2023

(30) Foreign Application Priority Data
May 4, 2021 (EP) 21171975.2

(51) Int. Cl. G03F 7/00; G03F 9/00

(52) U.S. Cl. CPC G03F 7/70633; G03F 7/70775; G03F 7/7085; G03F 9/7088

(57) ABSTRACT

Disclosed is a parallel metrology sensor system comprising a reference frame and a plurality of integrated optics sensor heads, each integrated optics sensor head configured to perform an independent measurement. Each of the integrated optics sensor heads is operable to measure its position with respect to the reference frame.

### CROSS-REFERENCE TO RELATED APPLICATIONS

This application claims priority of EP application 21171975.2 which was filed on 4 May 2021, and which is incorporated herein in its entirety by reference.

### FIELD OF INVENTION

The present invention relates to methods and apparatus usable, for example, in the manufacture of devices by lithographic techniques, and to methods of manufacturing devices using lithographic techniques. The invention relates more particularly to metrology sensors, such as position sensors.

### BACKGROUND ART

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of a die, one die, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. These target portions are commonly referred to as “fields”.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down (by the same apparatus or a different lithographic apparatus) in previous layers. For this purpose, the substrate is provided with one or more sets of alignment marks. Each mark is a structure whose position can be measured at a later time using a position sensor, typically an optical position sensor. The lithographic apparatus includes one or more alignment sensors by which positions of marks on a substrate can be measured accurately. Different types of marks and different types of alignment sensors are known from different manufacturers and different products of the same manufacturer.

In other applications, metrology sensors are used for measuring exposed structures on a substrate (either in resist and/or after etch). A fast and non-invasive form of specialized inspection tool is a scatterometer in which a beam of radiation is directed onto a target on the surface of the substrate and properties of the scattered or reflected beam are measured. Examples of known scatterometers include angle-resolved scatterometers of the type described in US2006033921A1 and US2010201963A1. In addition to measurement of feature shapes by reconstruction, diffraction based overlay can be measured using such apparatus, as described in published patent application US2006066855A1. Diffraction-based overlay metrology using dark-field imaging of the diffraction orders enables overlay measurements on smaller targets. Examples of dark field imaging metrology can be found in international patent applications WO 2009/078708 and WO 2009/106279 which documents are hereby incorporated by reference in their entirety. Further developments of the technique have been described in published patent publications US20110027704A, US20110043791A, US2011102753A1, US20120044470A, US20120123581A, US20130258310A, US20130271740A and WO2013178422A1. These targets can be smaller than the illumination spot and may be surrounded by product structures on a wafer. Multiple gratings can be measured in one image, using a composite grating target. The contents of all these applications are also incorporated herein by reference.

In many metrology applications, such as alignment or overlay metrology, it is desirable to measure as many targets/alignment marks as possible in as quick as time as possible. This enables higher order distortions and effects to be better captured and modeled without impacting throughput. As such, a metrology apparatus which can measure more targets/marks as present metrology apparatus within the same timescales is desirable.

### SUMMARY OF THE INVENTION

The invention in a first aspect provides a parallel metrology sensor system comprising: a reference frame; and a plurality of integrated optics sensor heads, each integrated optics sensor head configured to perform an independent measurement; wherein each of the integrated optics sensor heads is operable to measure its position with respect to the reference frame.

The above and other aspects of the invention will be understood from a consideration of the examples described below.

### BRIEF DESCRIPTION OF THE DRAWINGS

Embodiments of the invention will now be described, by way of example only, with reference to the accompanying drawings, in which:

FIG. 1 depicts a lithographic apparatus;

FIG. 2 illustrates schematically measurement and exposure processes in the apparatus of FIG. 1;

FIG. 3 schematically depicts a parallel metrology sensor system according to an embodiment;

FIG. 4 schematically depicts (a) a (partial) top view, (b) front view and (c) side view of the parallel metrology sensor system depicted in FIG. 3;

FIG. 5 schematically depicts (a) a (partial) top view, (b) front view and (c) side view of the parallel metrology sensor system depicted in FIG. 3 with actuation detail illustrated; and

FIG. 6 schematically depicts three alternative optical fiber coupling mechanisms to optically couple the optical fibers to the sensor head chips.

### DETAILED DESCRIPTION OF EMBODIMENTS

Before describing embodiments of the invention in detail, it is instructive to present an example environment in which embodiments of the present invention may be implemented.

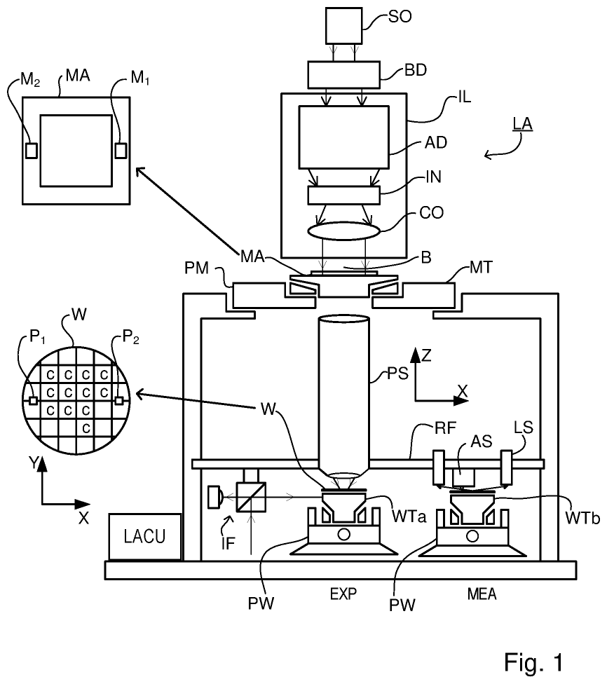

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations—an exposure station EXP and a measurement station MEA—between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

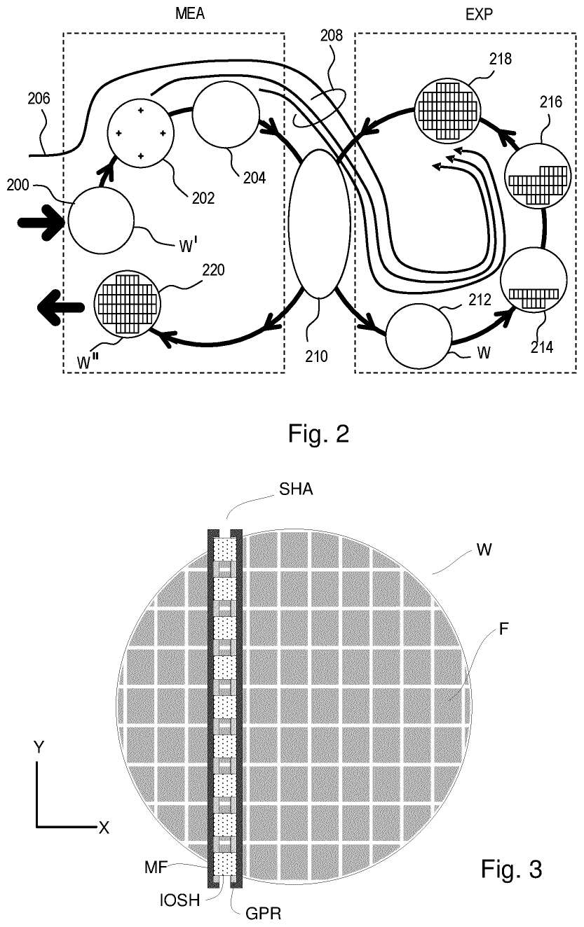

FIG. 2 illustrates the steps to expose target portions (e.g. dies) on a substrate W in the dual stage apparatus of FIG. 1. On the left hand side within a dotted box are steps performed at a measurement station MEA, while the right hand side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. These processing steps progressively introduce distortions in the substrate that must be measured and corrected for, to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

At 202, alignment measurements using the substrate marks P1 etc. and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid”, which maps very accurately the distribution of marks across the substrate, including any distortion relative to a nominal rectangular grid.

At step 204, a map of wafer height (Z) against X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. To these recipe data are added the measurements of wafer position, wafer grid and height map that were made at 202, 204, so that a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the ‘ideal’ grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

The skilled person will know that the above description is a simplified overview of a number of very detailed steps involved in one example of a real manufacturing situation. For example rather than measuring alignment in a single pass, often there will be separate phases of coarse and fine measurement, using the same or different marks. The coarse and/or fine alignment measurement steps can be performed before or after the height measurement, or interleaved.

It is increasingly desirable to measure an increasing number of metrology marks per wafer (e.g., in alignment and overlay metrology) to enable better corrections, thereby resulting in improved overlay performance. Most current alignment and overlay sensors are of a single-sensor head type. Present sensor head designs mean that it is very difficult to accommodate more than one such sensor head in a metrology tool. The sensor heads are typically too large and cannot be efficiently positioned next to each other. They are furthermore too expensive. As such, measuring an increased number of marks requires that this single sensor head measures each alignment mark faster and/or there is more measurement time available per wafer. However, there will always be a practical limit on measurement speed, and throughput requirements mean that measurement time cannot be increased too much, if at all. A consequence of this means that there is an effective practical limit in the number of alignment marks per wafer which can be measured for (in-line) alignment metrology.

However, significant wafer deformations occur at higher spatial frequencies than can be captured when measuring a typical number of marks. One particular example is the deformation due to the wafer-load-grid (chucking deformations resultant from the loading of the wafer onto a wafer stage). Such deformations occur on the scale of a field size (e.g., in the order of centimeters) and require hundreds of alignment marks to capture sufficiently. Furthermore, it is expected that other deformations will be better captured by measuring more marks.

Integrated optics is an emerging technology that can enable small, cheap optical sensors by manufacturing the sensors on-chip. Such integrated optics circuits are cheaper and smaller than conventional alignment sensor systems. In addition, they are printed with lithographic accuracy and are therefore expected to have good sensor-to-sensor matching.

A parallel metrology sensor system is therefore proposed which uses a plurality of integrated optics sensor heads in a sensor head array. Such a parallel metrology sensor system may be able to measure more than 200, 300, 400 or 500 alignment marks or other metrology targets at acceptable speed (e.g., to be throughput neutral with respect to present sensors).

The parallel metrology sensor system described in detail below will be described predominately in the context of a parallel alignment sensor system for performing wafer alignment (e.g., in-line wafer alignment) prior to performing an exposure on that wafer. However, it should be appreciated and understood that alignment is only one metrology application for which the teachings herein are applicable. The parallel metrology sensor system disclosed herein may be used for measuring other targets for other applications (e.g., overlay metrology, focus metrology, critical dimension metrology etc.). As such, the parallel metrology sensor system disclosed herein may be used for any metrology application for which present scatterometer or interferometer sensors are presently used, and in particular in the context of integrated circuit manufacture and/or monitoring thereof.

Parallelizing these integrated optics sensor heads into a parallel metrology system is not straightforward nor trivial for a number of reasons. Firstly, it is highly desirable that varying field sizes are accommodated as field sizes are not standard and may change from lot to lot. This implies that each sensor head should be moveable over a suitable range, e.g., of at least 30 mm. Also, the positions of each integrated optics sensor head (e.g., in 6 degrees of freedom) should be known within the same accuracy as the position of the alignment mark (e.g., within 0.1 nm). Additionally, the sensor heads should be positioned close to each other, which results in challenges with regard to optical input/output connections to these integrated optics sensor heads. A number of embodiments will be described which address these issues.

FIG. 3 shows a proposed parallel metrology system according to an embodiment. In this embodiment, nine integrated optics sensor heads IOSH are shown in a 1D sensor head array SHA forming a sensor stage arrangement. Also shown is part of the metrology frame MF or reference frame which supports and provides a reference for the integrated optics sensor heads IOSH. The integrated optics sensor heads IOSH are positioned in a column, with the separation between adjacent heads being between 2 mm and 30 mm, between 5 mm and 20 mm, between 7 mm and 15 mm or approximately 10 mm. The sensor heads may be moveable in the Y-direction to accommodate different field F sizes on wafer W. Of course, the number of integrated optics sensor heads IOSH per column or ID array may differ from 9; e.g., the sensor head array SHA may comprise between 3 and 20 integrated optics sensor heads IOSH, between 5 and 15 integrated optics sensor heads IOSH, or between 7 and 12 integrated optics sensor heads IOSH.

Additionally, more parallelization may be achieved by providing one or more additional columns or ID or 2D sensor head arrays SHA. In such an embodiment, each of the additional columns or 1D/2D sensor head arrays SHA may comprise its own sensor stage arrangement (i.e., the metrology system may comprise two or more separate stage arrangements, each comprising a different plurality of integrated optics sensor heads IOSH, such as a ID array or 2D array of sensor heads). In the context of this disclosure a sensor stage arrangement may comprise a plurality integrated optics sensor heads IOSH which are together moveable or actuatable as a group over the wafer, and therefore may comprise the necessary actuators to implement this actuation. Within the/each stage arrangement, as will be described in detail below, each of the integrated optics sensor heads IOSH may additionally be independently moveable in relation to each other over a limited range compared to the actuation range of the stage arrangement.

In some arrangements, it may be required to split the reference frame such that it comprises two or more portions which are individually moveable with respect to each other. In this manner, each array may move with respect to the other to accommodate various field sizes. In such an embodiment, it is proposed that at least one of the arrays is fixed to (or part of) the reference frame proper (i.e., a main portion of the reference frame). The other sensor arrays may each be comprised with a respective moveable portion of the metrology frame. These moveable portions of the metrology frame may be made sufficiently stiff and well connected to the reference frame such that it is able to act as a reference. As such, the moveable portion of the reference frame may be clamped (or otherwise rigidly connected) to the reference frame proper after moving, such that its position with respect to the reference frame proper is then well defined. As such, the reference frame moveable portions may comprise one or more of the same thermal properties, same mechanical properties and same stability as reference frame proper. In other embodiments, all the sensor arrays (or the sole array) may be mounted to such moveable reference frame portions.

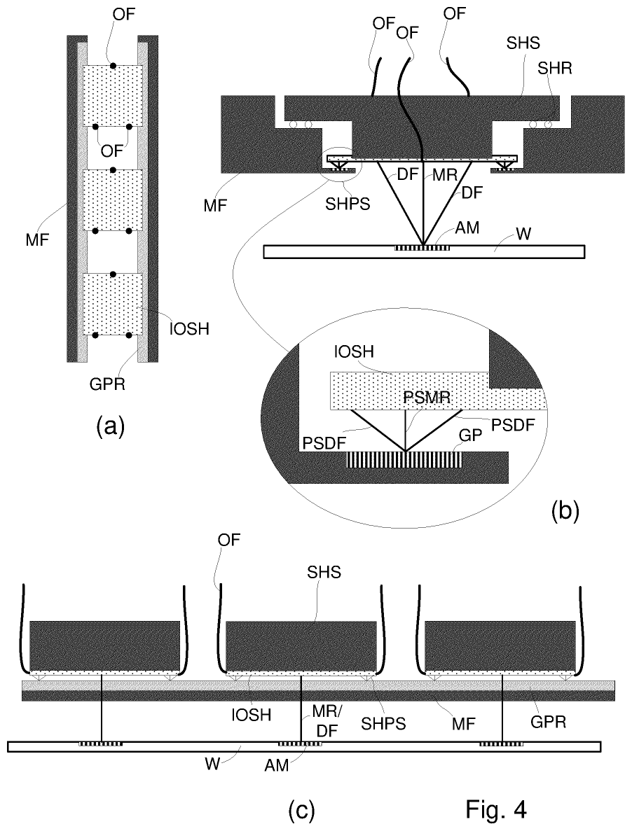

FIG. 4 depicts the arrangement of FIG. 3 in greater detail, and comprises (a) a (partial) top view, (b) front view and (c) side view of the parallel metrology sensor system. Each integrated optics sensor head IOSH is attached to a respective head module or sensor head slider SHS (these are not shown in FIG. 4(a)). The sensor head sliders SHS slide over rails SHR in the Y-direction under actuation of an actuator or motor (not shown). Such a motor may comprise a stepper or servo motor and may have a stroke of about 30 mm and accuracy of about 100 nm. The sensor head rail SHR can be considered to be integral with the metrology frame MF. Another motor may be provided to position the integrated optics sensor head IOSH chips in x-direction; e.g., with an accuracy of about 100 nm and range of approximately 1 μm.

The integrated optics sensor head IOSH may emit measurement radiation MR which may be scattered or diffracted by a metrology target (e.g., an alignment mark) AM on a wafer W. The scattered or diffracted radiation DF is captured and from this, and a readout system on the sensor head chip (or off-chip) can determine the alignment mark AM position (or other parameter of interest) from the scattered radiation.

The metrology frame MF may comprise one or more extrusions, reference rails or grid plate rails GPR between the wafer W and the sensor head IOSH. On each grid plate rail GPR, one or more reference structures or grid plates GP may be provided. Each grid plate may comprise a grid of lines (e.g., 1D or 2D periodic structure enabling sensor positioning in X and/or Y directions). For example, the pitches of these grid plates GP may be on the order of about 1 μm. Each grid plate GP may be etched directly into the metrology frame MF, or comprise an inlay from a different material.

The grid plates GP may be used by a sensor head positioning system SHPS to determine the position of each sensor head IOSH. In an embodiment, the sensor head positioning system SHPS may enable each integrated optics sensor head IOSH to read its own position (in one or both of the X and Y directions) with respect to the metrology frame MF. This may be achieved by the sensor head emitting positioning system measurement radiation PSMR at a reference structure or grid plate GP which is integral with the metrology frame MF. The resultant positioning system diffraction radiation PSDF is collected and a readout system on chip (or off-chip) determines the sensor head position. Such a readout system may be similar to that of the main metrology sensor part of the chip, and as such may have a similar accuracy (e.g., for example of about 0.1 nm). The readout system may be less complex than the main metrology system in that it may support only one wavelength-pitch combination, while the main metrology system may provide support for multiple wavelength-pitch combinations such as provided by present metrology/alignment sensors. Air fluctuations are unlikely to have a large impact because the sensor and grid plates are close to each other.

Optionally, detectors (not shown) may be provided to measure z-height with respect to the grid plates GP. This has the advantage of enabling tilts of the sensor head optical chip IOSH to be measured in-situ. Tilts, together with focus error, are large contributors to the alignment accuracy; by measuring tilts together with leveling information, it is possible to correct these errors.

Optical fibers OF transport the measurement radiation MR, PSMR to each integrated optics sensor head IOSH and extract the scattered/diffracted light DF, PSDF from the chip.

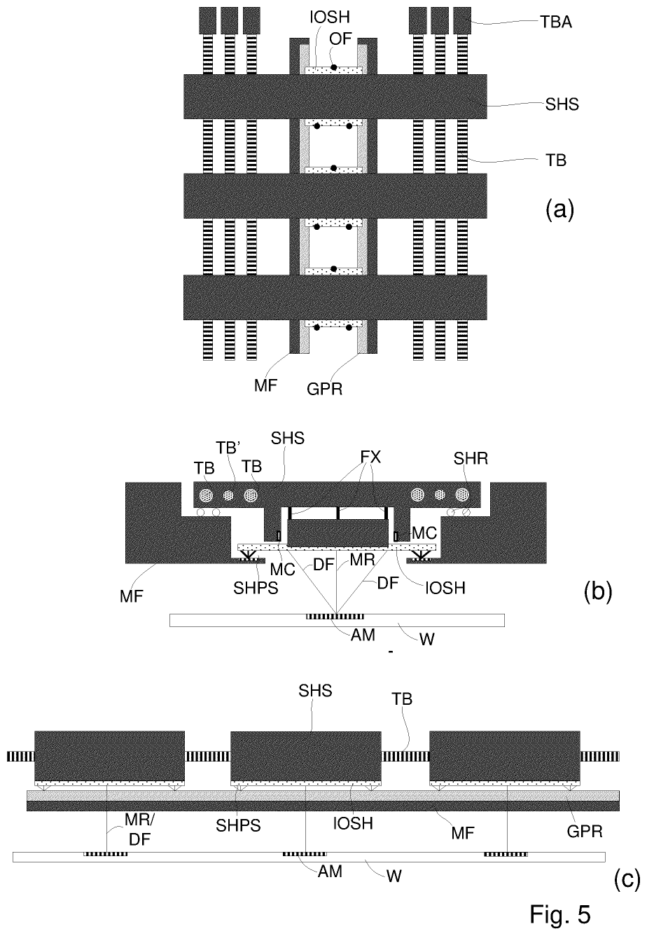

FIG. 5 shows the parallel metrology sensor system depicted in FIG. 4, with actuation detail illustrated. Once again, the Figure comprises (a) a (partial) top view, (b) front view and (c) side view of the parallel metrology sensor system. The actuation may be such that each integrated optics sensor head IOSH may be able to move in the Y direction over a range of between 10 mm and 50 mm, or between 20 mm or 40 mm (e.g., about 30 mm) with an accuracy of less than 100 nm.

Each integrated optics sensor head IOSH may be attached to a sensor head module or slider SHS (this time shown in the top level view of FIG. 5(a)). Each slider may comprise a first actuation arrangement comprising an internal thread which moves over a complementary threaded beam TB, such that, by rotating the beam TB (for example using a threaded beam actuator TBA), the slider SHS moves. Furthermore, each slider may have clear out holes to pass the beams of other sliders. This latter feature is shown in FIG. 5(b), where the threaded beam TB′ is actuating the slider SHS shown, with the other threaded beams TB passing through cut-out holes. In this way each sensor head IOSH can be actuated independently (or at least those between the end sensor heads at each end of the array). The sensor head positioning system SHPS may be used for feedback to the respective actuator TBA. By way of specific example, the beam TB may have a thread of 200 μm such that a 1/2000th turn (0.18 deg) would result in a 100 nm shift. The actuators TBA may comprise a servo motor or piezo motor. It can be appreciated that the threaded beams TB could be accommodated within the sliders SHS at a position above the sensor heads, rather than either side as shown, thereby making the system more compact in X-direction.

Actuation of the each sensor head in the X-direction may be provided via a second actuation arrangement comprising, for example, a flexible coupling or flexure FX and magnet-coil MC combination between two sections of the slider SHS (one comprising the sensor head SH) or between slider SHS and sensor head SH. The coils MC can be positioned on the slider itself (as depicted in FIG. 5(b)) or inside the metrology frame MF. If located inside the metrology frame MF, a cooling system (e.g., water cooling) may be provided. The coil current may be determined by a feedback loop of the sensor head positioning system SHPS. Control in the X-direction may cover a range of greater than 0.5 μm (e.g., between 0.5 μm and 2 μm or about 1 μm) at an accuracy of less than 100 nm.

Other actuation methods are also possible. For instance actuation in either or both of the X and Y directions may be performed using Lorentz motors, such that the sensor head chips hover in a magnetic field.

The integrated optics sensor heads each need to be provided with light and power/communication cabling. The optical fiber and electronic cabling can be guided above the sliders, for example. While the power/communication cabling can be coupled to the integrated optics sensor heads relatively straightforwardly, the optical fiber coupling presents greater difficulty due to its limited bending radius. In particular, the cabling should have sufficient slack to allow the e.g., 30 mm travel range of each sensor head. As such, the optical connection from fiber to sensor head chip should be less than 10 mm due to the spacing of the sensor heads. However, standard side-connection is problematic because of the large bending radius of optical fibers, which is typically greater than ˜20 mm. There are bend sensitive fibers which have a bending radius closer to 5 mm. However, even if these were used, it remains a challenge when the spacing between the sensor heads is reduced. As such, a fiber connected at ˜90 degrees to the sensor head surface is preferred.

Side-connection of an optical fiber is the most efficient method for coupling light into the sensor head chip, such that the fiber end is introduced parallel to the sensor head. However, the minimum bending radius and proposed sensor head spacing will make standard side-connection impossible. Furthermore, the fibers cannot leave the chip in the X-direction of the sensor head chip as they will foul the grid plates and/or the space between the reference frame and the sensor heads may be too restricted. Optical fibers also cannot use a standard grating coupling as their bending radius is too large, meaning that the fiber will contact the wafer.

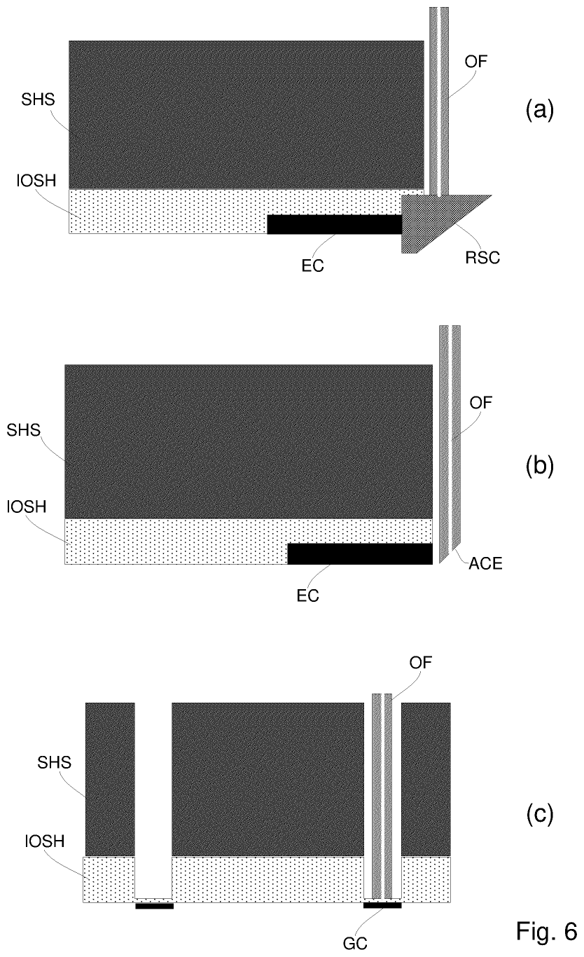

Therefore, methods will be disclosed which enable coupling of radiation from a fiber to an integrated optics chip and vice versa at an angle of about 90 degrees (e.g., greater than 70 degrees, greater than 80 degrees or greater than 85 degrees and/or no more than 95 degrees, no more than 100 degrees or no more than 110 degrees). Note that an angle less than 90 degrees may mean that the fiber cuts though the sensor head module, which is not desirable. Therefore, the angle may be such that the fiber does not cut through the sensor head module. These methods are illustrated in FIG. 6, and are applicable to UV/visible/IR wavelengths.

FIG. 6(a) discloses an optical fiber OF coupling embodiment where an additional radiation steering component RSC is provided between an edge coupler EC of the optical chip IOSH and the input or output end (as appropriate) of optical fiber OF. The radiation steering component RSC has the function of steering the radiation from the optical fiber OF through approximately 90 degrees. direction. The radiation steering component RSC may comprise, for example, a mirrored surface which steers the light under an angle of 90 degrees. The mirrored surface can have a focusing behavior to enhance coupling efficiency. The optical fiber(s) may be mounted to this radiation steering component RSC which is then mounted to the side of the optical chip IOSH. The light from the chip is then coupled into the fiber and vice versa. Other radiation steering component RSC may comprise a reflective prism, for example.

FIG. 6(b) discloses an optical fiber OF coupling embodiment where the optical fiber OF itself is configured for the desired right-angle coupling. In such an embodiment, the optical fiber can be cut or polished under an angle such that it comprises an angle cut end ACE. Internal reflection at this angle cut end ACE causes the radiation to exit at the optical fiber OF at an angle of about 90 degrees with respect to the fiber core. The fiber can then be affixed at a straight angle to the edge connector EC on the integrated optics chip IOSH. Note that the edge connector may comprise a waveguide connected to the other optical components on the chip IOSH, and not a separate component.

FIG. 6(c) discloses an optical fiber OF coupling embodiment based on a through-silicon (or whatever material the chip comprises) optical via. The optical chip IOSH can be etched from the bottom such that the optical fiber OF can be introduced close to the optical layer from the back side. In the optical layer there is a grating coupler GC to couple light into or out of the plane of the chip. The via may be etched through the slider/sensor head module SHS body and through most (but not all) of the chip material. As such, the radiation will have to travel through a small membrane of the chip material between optical fiber OF and grating coupler GC, but this can be made low loss for the radiation. Etching of the vias may be performed, for example, using a reactive ion process. Note that the optical fiber OF may be tilted in such an embodiment, such that the fiber has a small tilt with respect to the grating coupler. A variation of this embodiment may comprise extending the optical chip IOSH each side by a small amount (e.g., by about 100 μm) and attaching the grating coupler to these extended edges of the chip. The grating coupler may still be comprised on a membrane as in the illustrated embodiment. The advantage of this variation is that there is no need to etch through the slider SHS.

Another coupling alternative may comprise guiding the optical fibers through channels in the metrology frame such that they enter through the side of the assembly. For example, the channels may be provided level with the sensor head IOSH through the metrology frame, coming from either side of the metrology frame as it is depicted in FIGS. 4(b) and 5(b). However, this does comprise making cuts in into the metrology frame, thereby weakening its mechanical stability. Another alternative, which is particularly applicable to the embodiment illustrated in FIG. 6(c) when infra-red measurement radiation is used, may comprise providing the radiation through the chip. However, this leads to reflection losses as the light enters the chip (while silicon is transparent for infra-red and losses inside the chip will be negligible, there will be a loss at the entrance due to reflection).

In another embodiment, each sensor head may be provided with on-chip light sources and/or detectors to obviate the need for an optical fiber connection to and/or from the chip, e.g., such that only electrical connections are required.

Such a parallel metrology sensor system as disclosed herein, comprising a single column of 10 sensor heads may be able to perform each parallel measurement (including stage movement) in about 75 ms. As such, within a typical present fine wafer alignment time of 6 seconds, 80 stage positions and therefore 10*80=800 alignment marks can be measured potentially without affecting throughput. Of course, there will other limitation which impact measurement speed, such as the sampling scheme used and the need to perform measurements at the edges of the wafer.

While specific embodiments of the invention have been described above, it will be appreciated that the invention may be practiced otherwise than as described.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens”, where the context allows, may refer to any one or combination of various types of optical components, including refractive, reflective, magnetic, electromagnetic and electrostatic optical components. Reflective components are likely to be used in an apparatus operating in the UV and/or EUV ranges.

Embodiments of the present disclosure can be further described by the following clauses.

1. A parallel metrology sensor system comprising:
a reference frame; and
a plurality of integrated optics sensor heads, each integrated optics sensor head configured to perform an independent measurement;
wherein each of the integrated optics sensor heads is operable to measure its position with respect to the reference frame.

2. The parallel metrology sensor system as in clause 1, wherein each of the integrated optics sensor heads comprises a respective sensor head positioning system for measuring the position of its respective integrated optics sensor head with respect to the reference frame.

3. The parallel metrology sensor system as in clause 2, wherein each sensor head positioning system is operable to emit positioning system measurement radiation from its respective integrated optics sensor head and capture scattered radiation, scattered from a reference structure on said reference frame, via said respective integrated optics sensor head.

4. The parallel metrology sensor system as in clause 3, wherein the reference structure comprises a one dimensional or two dimensional periodic structure etched into, embedded into or affixed to said reference frame.

5. The parallel metrology sensor system as in clause 2, 3 or 4, wherein the sensor head positioning system is operable to measure the position of its respective integrated optics sensor head with respect to the reference frame in each direction parallel to the substrate plane.

6. The parallel metrology sensor system as in any of clauses 2 to 5, wherein the sensor head positioning system is operable to measure the position of its respective integrated optics sensor head with respect to the reference frame in a direction perpendicular to the substrate plane.

7 The parallel metrology sensor system as in any preceding clause, further comprising: at least one stage arrangement for said plurality of integrated optics sensor heads;
wherein said at least one stage arrangement enables spacing between the integrated optics sensor heads to be varied.

8. The parallel metrology sensor system as clause 7, wherein said at least one stage arrangement comprises a respective sensor head module for each integrated optics sensor head, said sensor head modules being moveable independently thereby enabling each of the integrated optics sensor heads to be moved independently in at least a first direction parallel to a substrate plane.

9. The parallel metrology sensor system as in clause 8, wherein said plurality of integrated optics sensor heads are arranged in a 1-dimensional array along said first direction for each stage arrangement of said at least one stage arrangement.

10. The parallel metrology sensor system as in clause 8 or 9, wherein each of said sensor head modules comprises a respective first actuator arrangement for moving said sensor head module in said first direction.

11. The parallel metrology sensor system as in clause 10, wherein said first actuator arrangement comprises a internal screw thread, threaded beam complementary to said and internal screw thread and actuator for turning the threaded beam.

12. The parallel metrology sensor system as in any of clauses 8 to 11, wherein said at least one stage arrangement enables each of the integrated optics sensor heads to be moved independently in each direction parallel to the substrate plane.

13. The parallel metrology sensor system as in clause 12, wherein each of said sensor head modules comprises a respective second actuator arrangement for moving said sensor head module in said second direction.

14. The parallel metrology sensor system as in clause 13, wherein said second actuator arrangement comprises a coil and magnet arrangement and a flexible coupling at a location between the integrated optics sensor head and at least a portion of the sensor head module supported by the metrology frame.

15. The parallel metrology sensor system as in any of clauses 7 to 14, wherein each said at least one stage arrangement comprises between 3 and 20 integrated optics sensor heads.

16. The parallel metrology sensor system as in any of clauses 7 to 14, wherein each said at least one stage arrangement comprises between 5 and 15 integrated optics sensor heads

17. The parallel metrology sensor system as in any of clauses 7 to 16, comprising a plurality of said stage arrangements.

18. The parallel metrology sensor system as in any preceding clause, wherein each of said integrated optics sensor heads comprises one or more optical fibers to transport measurement radiation to and/or transport a measurement signal from said integrated optics sensor head, each of said one or more optical fibers comprising an optical coupling arrangement operable to optically couple the optical fiber to said integrated optics sensor heads at a coupling angle between 70 degrees and 110 degrees.

19. The parallel metrology sensor system as in clause 18, wherein said optical coupling arrangement comprises a radiation steering component for steering the radiation under said coupling angle.

20. The parallel metrology sensor system as in clause 19, wherein the radiation steering component comprises a mirrored surface or prism.

21. The parallel metrology sensor system as in clause 18, wherein said optical coupling arrangement comprises an obliquely cut or polished end of the optical fiber such that said optical fiber emits and/or collects radiation through said coupling angle.

22. The parallel metrology sensor system as in any of clauses 19 to 21, wherein said optical coupling arrangement comprises an edge coupler to couple said radiation into and/or out of its respective integrated optics sensor head.

23. The parallel metrology sensor system as in clause 18, wherein said optical coupling arrangement comprises a through-via arrangement such that each optical fiber is routed through a backside of its respective integrated optics sensor head.

24. The parallel metrology sensor system as in clause 23, wherein said optical coupling arrangement comprises a grating coupler to couple said radiation into and/or out of its respective integrated optics sensor head.

25. The parallel metrology sensor system as in any preceding clause, wherein the parallel metrology sensor system comprises an alignment sensor.

26. A lithographic exposure apparatus operable to expose a pattern on a substrate, said lithographic exposure apparatus comprises the parallel metrology sensor system as in clause 25 for performing alignment of said substrate prior to performing an exposure on said substrate.

27. The parallel metrology sensor system as in any of clauses 1 to 24, wherein the parallel metrology sensor system comprises an overlay, focus and/or critical dimension metrology device.

The breadth and scope of the present invention should not be limited by any of the above-described exemplary embodiments, but should be defined only in accordance with the following claims and their equivalents.

1. A parallel metrology sensor system comprising:
a reference frame; and
a plurality of integrated optics sensor heads, each integrated optics sensor head configured to perform an independent measurement;
wherein each of the integrated optics sensor heads is operable to measure its position with respect to the reference frame and wherein each of the integrated optics sensor heads comprises a respective sensor head positioning system for measuring the position of its respective integrated optics sensor head with respect to the reference frame.

2. (canceled)

3. The parallel metrology sensor system as claimed in claim 1, wherein each sensor head positioning system is operable to emit positioning system measurement radiation from its respective integrated optics sensor head and capture scattered radiation, scattered from a reference structure on said reference frame, via said respective integrated optics sensor head.

4. The parallel metrology sensor system as claimed in claim 3, wherein the reference structure comprises a one dimensional or two dimensional periodic structure etched into, embedded into or affixed to said reference frame.

5. The parallel metrology sensor system as claimed in claim 1, wherein the sensor head positioning system is operable to measure the position of its respective integrated optics sensor head with respect to the reference frame in each direction parallel to a substrate plane.

6. The parallel metrology sensor system as claimed in claim 1, wherein the sensor head positioning system is operable to measure the position of its respective integrated optics sensor head with respect to the reference frame in a direction perpendicular to a substrate plane.

7. The parallel metrology sensor system as claimed in claim 1, further comprising:
at least one stage arrangement for said plurality of integrated optics sensor heads;
wherein said at least one stage arrangement enables spacing between the integrated optics sensor heads to be varied.

8. The parallel metrology sensor system as claimed in claim 7, wherein said at least one stage arrangement comprises a respective sensor head module for each integrated optics sensor head, said sensor head modules being moveable independently thereby enabling each of the integrated optics sensor heads to be moved independently in at least a first direction parallel to a substrate plane.

9. The parallel metrology sensor system as claimed in claim 8, wherein each of said sensor head modules comprises a respective first actuator arrangement for moving said sensor head module in said first direction.

10. The parallel metrology sensor system as claimed in claim 8, wherein said at least one stage arrangement enables each of the integrated optics sensor heads to be moved independently in each direction parallel to the substrate plane.

11. The parallel metrology sensor system as claimed in claim 1, wherein each of said integrated optics sensor heads comprises one or more optical fibers to transport measurement radiation to and/or transport a measurement signal from said integrated optics sensor head, each of said one or more optical fibers comprising an optical coupling arrangement operable to optically couple the optical fiber to said integrated optics sensor heads at a coupling angle between 70 degrees and 110 degrees.

12. The parallel metrology sensor system as claimed in claim 11, wherein said optical coupling arrangement comprises a radiation steering component for steering the radiation under said coupling angle.

13. The parallel metrology sensor system as claimed in claim 11, wherein said optical coupling arrangement comprises an obliquely cut or polished end of the optical fiber such that said optical fiber emits and/or collects radiation through said coupling angle.

14. The parallel metrology sensor system as claimed in claim 12, wherein said optical coupling arrangement comprises an edge coupler to couple said radiation into and/or out of its respective integrated optics sensor head.

15. The parallel metrology sensor system as claimed in claim 11, wherein said optical coupling arrangement comprises a through-via arrangement such that each optical fiber is routed through a backside of its respective integrated optics sensor head.

16. The parallel metrology sensor system as claimed in claim 15, wherein said optical coupling arrangement comprises a grating coupler to couple said radiation into and/or out of its respective integrated optics sensor head.

17. The parallel metrology sensor system as claimed in claim 1, wherein the parallel metrology sensor system comprises an alignment sensor.

18. A lithographic exposure apparatus operable to expose a pattern on a substrate, said lithographic exposure apparatus comprises the parallel metrology sensor system as claimed in claim 17 for performing alignment of said substrate prior to performing an exposure on said substrate.

19. The parallel metrology sensor system as claimed in claim 1, wherein the parallel metrology sensor system comprises an overlay, focus and/or critical dimension metrology device.

20. The parallel metrology sensor system as claimed in claim 13, wherein said optical coupling arrangement comprises an edge coupler to couple said radiation into and/or out of its respective integrated optics sensor head.
